(19) United States
(12) Patent Application Publication
(10) Pub. No.: US 2025/0342811 A1
(43) Pub. Date: Nov. 6, 2025

(54) TUNABLE RESONATOR ARRAY

(71) Applicant: INTERNATIONAL BUSINESS MACHINES CORPORATION, ARMONK, NY (US)

(72) Inventors: SETH ELIJAH BARD, POUGHKEEPSIE, NY (US); YUANCHEN HU, PEEKSKILL, NY (US); BRANDON M. KOBILKA, FISHKILL, NY (US); CAMILLO SASSANO, DURHAM, NC (US)

(21) Appl. No.: 18/655,811

(22) Filed: May 6, 2024

(51) Int. Cl. G10K 11/172; H03H 9/02; H03H 9/205

(52) U.S. Cl. CPC G10K 11/172; H03H 9/205; H03H 2009/02165

(57) ABSTRACT

Methods, apparatus, and systems for tuning a resonator array may include receiving, by a resonator array including a plurality of resonators, a signal, wherein each of the plurality of resonators is configured to attenuate sound at a specific frequency and includes a cavity and a neck coupled to the cavity, and altering, by a physical mechanism coupled to the cavities of the resonators and based on the received signal, the specific frequency of sound attenuated by each of the plurality of resonators, including altering a volume of the cavity included in each of the plurality of resonators.

### BACKGROUND

### Field of the Disclosure

The field of the disclosure is data processing, or, more specifically, methods, apparatus, and systems for tuning a resonator array.

### Description of Related Art

Resonators have a specific resonating frequency. Some resonators are configured to reduce or attenuate sound at the specific resonating frequency of the resonator. Resonator arrays include multiple resonators grouped together in order to maximize sound attenuation for the specific resonating frequency associated with the resonators. Resonators can be tuned to alter the frequency attenuated by them by altering one or more physical characteristics of the resonator. By altering multiple resonators included within a resonator array, multiple frequencies may be targeted for attenuation by tuning different parts of the array (or by tuning multiple arrays that are grouped together). It would be beneficial to have a resonator array that allows for the tuning of the resonator array, where all of the resonators are tuned simultaneously, using a single physical mechanism.

### SUMMARY

Methods and systems for tuning a resonator array according to various embodiments are disclosed in this specification. In accordance with one aspect of the present disclosure, a method of tuning a resonator array may include receiving, by a resonator array including a plurality of resonators, a signal, wherein each of the plurality of resonators is configured to attenuate sound at a specific frequency and includes a cavity and a neck coupled to the cavity, and altering, by a physical mechanism coupled to the cavities of the resonators and based on the received signal, the specific frequency of sound attenuated by each of the plurality of resonators, including altering a volume of the cavity included in each of the plurality of resonators.

In accordance with another aspect of the present disclosure, a tunable resonator array may include a plurality of resonators each configured to attenuate sound at a specific frequency, wherein each of the plurality of resonators includes a cavity and a neck coupled to the cavity, and a physical mechanism configured to change the specific frequency of sound attenuated by each of the plurality of resonators, including alter, by the physical mechanism, a volume of the cavity included in each of the plurality of resonators.

The foregoing and other objects, features and advantages of the disclosure will be apparent from the following more particular descriptions of exemplary embodiments of the disclosure as illustrated in the accompanying drawings wherein like reference numbers generally represent like parts of exemplary embodiments of the disclosure.

### BRIEF DESCRIPTION OF THE DRAWINGS

FIG. 1 shows an example line drawing of a tunable resonator array in accordance with embodiments of the present disclosure.

FIG. 2 shows an example line drawing of a tunable resonator array in a different configuration in accordance with embodiments of the present disclosure.

FIG. 3 shows an example line drawing of another tunable resonator array in accordance with embodiments of the present disclosure.

FIG. 4 is a flowchart of an example method for tuning a resonator array according to some embodiments of the present disclosure.

FIG. 5 is a line drawing of a system configured for tuning a resonator array in accordance with embodiments of the present disclosure.

FIG. 6 is a line drawing of another system configured for tuning a resonator array in accordance with embodiments of the present disclosure.

### DETAILED DESCRIPTION

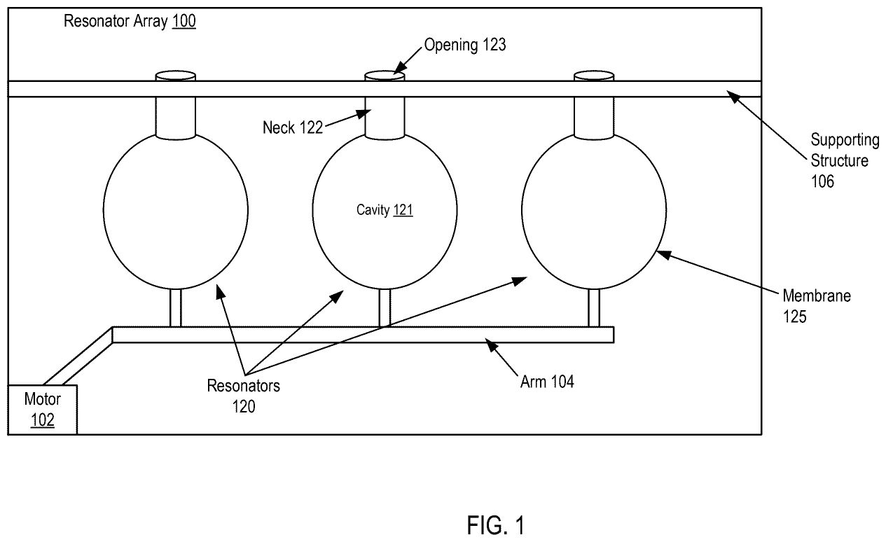

Exemplary methods, apparatus, and systems for tuning a resonator array in accordance with the present disclosure are described with reference to the accompanying drawings, beginning with FIG. 1. FIG. 1 sets forth an example line drawing of a tunable resonator array in accordance with embodiments of the present disclosure. The example of FIG. 1 shows a resonator array 100 including multiple resonators 120, a supporting structure 106, an arm 104, and a motor 102.

The example resonators 120 included in the resonator array 100 each include a neck 122, an opening 123 in the neck, and a cavity 121 coupled to the neck. The cavity 121 of each resonator is surrounded by a membrane 125 coupled to the neck 122. The membrane of each resonator 120 is coupled to a mechanical arm (arm 104), which is in turn coupled to a motor 102 included as part of the resonator array. The arm 104 of FIG. 1 depicts one type of mechanical connection. In another embodiment, the arm may instead be a wire, cord, plate, or other mechanical connection. In the example of FIG. 1, the motor is included in the resonator array. However, in another embodiment (not shown in FIG. 1) the motor, or some other type of actuator configured to move the arm, is external to the resonator array.

The example resonators 120 of FIG. 1 are each configured to attenuate sound of a particular frequency, where the frequency of sound attenuated is dependent on various attributes of the resonator. Such a resonator as depicted in FIG. 1 is a Helmholtz resonator. The frequency (f) attenuated by such a resonator is equal to the product of the speed of sound (v) divided by 2Pi and the square root of the ratio of the neck opening cross sectional area (A) to the product of the neck length (l) and the cavity volume (V). See the equation below:

$$f = \frac{v}{2 π} \sqrt{\frac{A}{Vl}}$$

The resonator array 100 is configured to move the arm 104 using the motor 102 to change the geometry and volume of the cavity 121 of each resonator 120 by moving the membrane 125. In such an embodiment, the membrane is flexible and configured to move and change shapes based on the position of the arm. The supporting structure 106 holds the resonators in place while the arm controls the shape (and thus the volume) of the resonator cavities. As shown in the above formula, the frequency of sound attenuated by the resonators can be controlled by controlling the volume of the cavity, such as via a physical mechanism included within the resonator array. In the example of FIG. 1, the physical mechanism is a mechanical arm (arm 104) that moves the membrane to either compress the cavity (making the cavity volume smaller), stretch the cavity (making the cavity volume larger), or shear the cavity to the side (making the cavity volume smaller).

The example supporting structure 106 is configured to hold the resonators in place while the arm controls the shape and volume of the resonator cavities. In the example of FIG. 1, the supporting structure 106 is an elongated bar or post anchored to the structure (such as a frame) of the resonator array and coupled to the neck of each of the resonators. In another embodiment, the supporting structure may be coupled to any part of the resonator and may be made up of any type of structure configured to keep the resonator in place while controlling the cavity volume. For example, in another embodiment, the supporting structure is a solid surface (such as a plate or some other surface along a continuous plane, whether flat or curved) where the neck of each resonator is flush to the surface. In such an embodiment, each neck would act as a hole in the surface of the supporting structure.

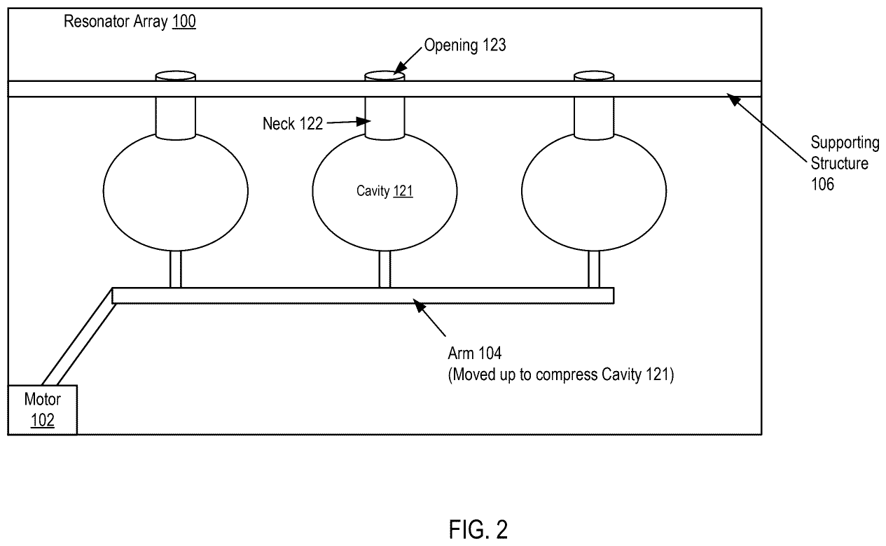

FIG. 2 shows the resonator array 100 of FIG. 1, but with the arm 104 moved upwards to compress the cavity 121 of the resonators. Specifically, the example resonator array of FIG. 2 is depicted with the resonators having a smaller volume than the resonators depicted in FIG. 1. In such an example, the motor 102 has operated to move the arm 104 upwards towards the necks of the resonators, thereby compressing the cavity of the resonators. By shrinking the size of the cavity volume for the resonators, the resonator array increases the frequency of sound that the resonator array attenuates. In another embodiment, where the resonator array increases the cavity volume of the resonators, the resonator array decreases the frequency of sound that the resonator array attenuates.

The example resonator array of FIG. 2 and FIG. 1 include three resonators 120. However, in other embodiments, the resonator array may include any number of resonators. The resonators 120 of resonator array 100 are shown as being identical in size and type. In other embodiments, the resonator array can include groups of multiple different types or sizes of resonators (so as to target multiple different frequencies of sound). The example resonator array of FIG. 2 and FIG. 1 depicts the resonators as being positioned in a single row, side by side for ease of explanation. In other embodiments, the resonators may be positioned in a grid three dimensionally, in a circle, or any other pattern. In an embodiment where the resonators are positioned relative to one another in a grid, the arm 104 may be made up of a series of arms linked to one another to contact all of the resonators at once and allow for a single actuation by the motor 102 to adjust the volume of all of the resonator cavities.

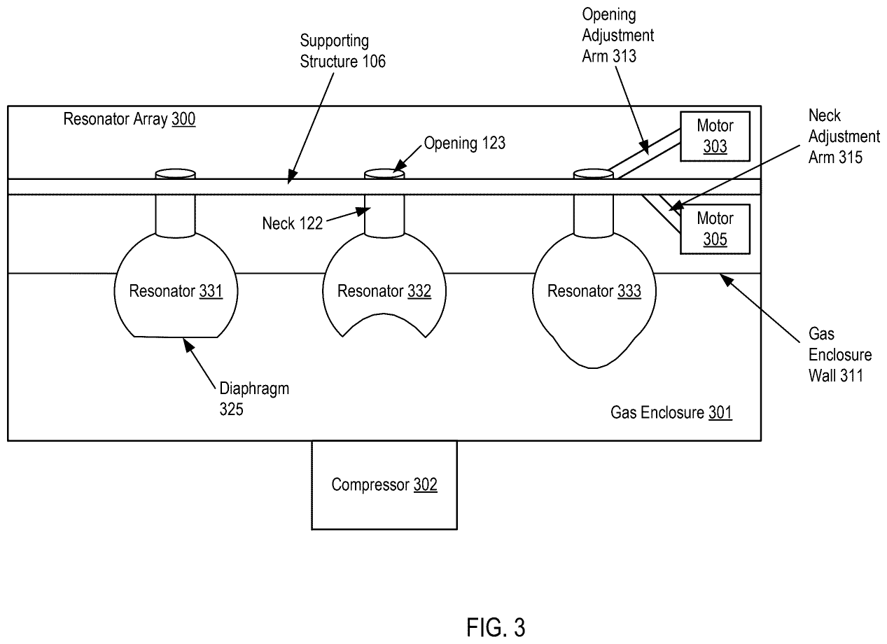

For further explanation, FIG. 3 sets forth a line drawing of another tunable resonator array in accordance with embodiments of the present disclosure. The resonator array 300 of FIG. 3 includes multiple resonators (such as resonator 331, resonator 332, and resonator 333), supporting structure 106, compressor 302, motor 303, motor 305, neck adjustment arm 315, opening adjustment arm 313, and gas enclosure wall 311 forming the gas enclosure 301. The resonators included within the resonator array 300 differ from the resonators included in resonator array 100 of FIG. 1 and FIG. 2. That is, rather than the entire cavity of each resonator being made up of a flexible membrane (as shown in FIG. 1), the resonators of FIG. 3 include a diaphragm 325 on its bottom surface. In such an embodiment, the remaining walls of the resonator cavity are rigid, while the diaphragm 325 is made up of a flexible material and is configured to move in or out of the cavity to control the cavity's volume.

The resonator array 300 of FIG. 3 differs from the resonator array 100 of FIG. 1 in how the volume of the resonators is altered. Rather than adjusting the volume of the cavities using a motor and an arm (as shown in FIG. 1), the resonator array 300 of FIG. 3 adjusts the resonator's cavity volume using a pneumatic mechanism. For example, FIG. 3 includes a compressor 302 configured to control the pressure of gas in the resonator array. While FIG. 3 shows the compressor 302 as being positioned external to the resonator array, in other embodiments the compressor may be included within the housing of the resonator array.

The resonator array 300 of FIG. 3 includes a gas enclosure wall 311 that isolates the air (or any other gas) surrounding the bottom half of the resonators and their diaphragms. The resonator array (or a controller included within it) is configured to operate compressor 302 to control the gas pressure within the gas enclosure 301 to effect a change in the shape and position of each of the resonator diaphragms 325.

As shown in FIG. 3, each of the resonators are depicted with diaphragms at different positions for purposes of explanation. However, during normal operation of the resonator array, the diaphragms of all the resonators coupled to the compressor 302 will be uniform in position. In an embodiment where a resonator array includes multiple compressors, each coupled to a set of resonators, each set of resonators may be at their own position corresponding to the pressure of the gas enclosure coupled to their associated compressor. In such an embodiment, multiple frequencies may be targeted for attenuation by a single resonator array. The diaphragm of resonator 331 is shown as being in a neutral position, which occurs when the compressor maintains the gas in gas enclosure 301 at atmospheric pressure (the pressure of the air surrounding the resonator array 300).

The diaphragm of resonator 332 is shown as being in a compressed position, which occurs when the compressor 302 maintains the gas in gas enclosure 301 at a pressure that is greater than the atmospheric pressure surrounding the resonator array 300. By increasing the pressure of the gas enclosure, and thus causing the diaphragm to bend inward towards the resonator's cavity, the effective volume of the resonator 332 is made smaller (when compared to the cavity of resonator 331), which in turn increases the frequency of sound that the resonator 332 attenuates.

The diaphragm of resonator 333 is shown as being in an expanded position, which occurs when the compressor 302 maintains the gas in gas enclosure 301 at a pressure that is less than the atmospheric pressure surrounding the resonator array 300. By decreasing the pressure of the gas enclosure, and thus causing the diaphragm to bend outward away from the resonator's cavity, the effective volume of the resonator 333 is made larger (when compared to the cavity of resonator 331), which in turn decreases the frequency of sound that the resonator 333 attenuates.

While FIG. 3 shows the resonator array as using a pneumatic mechanism (such as compressor 302 coupled with gas enclosure 301) for tuning the resonators, another embodiment of the present disclosure utilizes a hydraulic mechanism in its place. Such an embodiment requires a hydraulic motor or piston that controls the pressure of fluid included in the fluid enclosure surrounding the resonator diaphragms (not shown in FIG. 3). Such an embodiment would function much in the same way as the pneumatic embodiment depicted here in FIG. 3.

The resonator array 300 of FIG. 3 also includes one or more motors (such as motor 303 and motor 305), an opening adjustment arm 313 coupling motor 303 to the opening of a resonator, and a neck adjustment arm 315 coupling motor 305 to the neck of a resonator. While FIG. 3 shows the neck adjustment arm 315 and the opening adjustment arm 313 as being connected to only one resonator (333), in other embodiments, the neck adjustment arm 315 and the opening adjustment arm 313 are each connected to multiple resonators, or all the resonators included in the resonator array. The neck adjustment arm 315 is configured to modify the length of the neck 122 of the resonators coupled to the arm. The opening adjustment arm 313 is configured to modify the diameter of the neck's opening 123 of the resonators coupled to the arm. In another embodiment, a single arm may be configured to modify multiple properties of the resonators in the resonator array (such as the neck length and the opening diameter).

For example, by increasing the opening of the necks on the resonators, the resonator array increases the frequency attenuated. In another example, by decreasing the opening of the necks on the resonators, the resonator array decreases the frequency attenuated. In another example, by increasing the length of the necks on the resonators, the resonator array decreases the frequency attenuated. In another example, by decreasing the length of the necks on the resonators, the resonator array increases the frequency attenuated.

While FIG. 3 shows a single physical mechanism for controlling both the neck length and diameter of the neck's opening, other embodiments of the present disclosure include separate physical mechanisms for controlling each resonator attribute. Accordingly, the resonator array may include up to three different physical mechanisms for controlling three different aspects of the resonator's geometry that affect the frequency of sound attenuated by the resonator array (such as the volume of the cavity, the length of the neck, and the diameter of the neck's opening). Any number of these three physical mechanisms may be operated independently by the array or controller, or simultaneously.

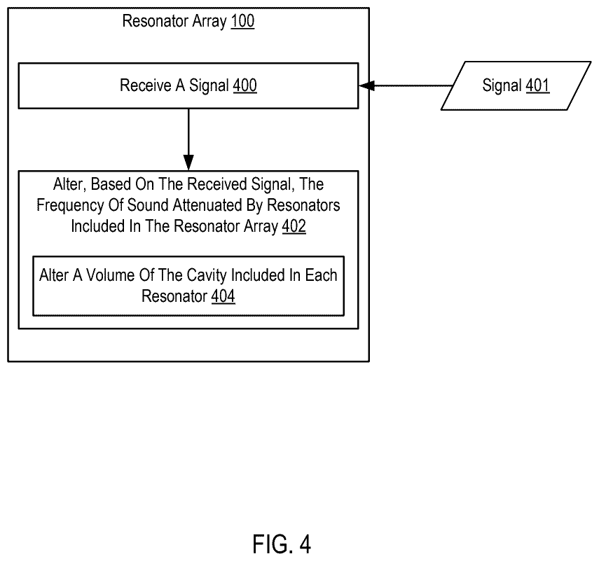

For further explanation, FIG. 4 sets forth a flow chart illustrating an exemplary method of tuning a resonator array according to embodiments of the present disclosure. The method of FIG. 4 includes receiving 400 a signal 401. Receiving a signal 401 may be carried out by a controller coupled to (or included within) the resonator array receiving signal 401. Signal 401 may come from a measurement device that assesses the system operational characteristics pertaining to noise emission. In one embodiment, the signal may come from a microphone positioned proximate to the resonator array. The signal 401 may indicate a particular frequency associated with sound proximate to the resonator array. For example, a resonator array may receive a signal from a microphone, or from a system coupled to a microphone, that indicates the most prominent frequency of sound that is proximate to the resonator array, which is useful for determining which frequencies the resonator array should be tuned for when attenuating sound. In another embodiment, the signal 401 is based on a measurement of a fan speed, which is translated into a frequency of interest (for attenuation) using a formula or look-up table (such as from a database) that is coupled to the resonator via an electronic processing element (such as a computer, a processor, and the like). In another embodiment, the signal is taken from position sensors of components interacting with the sound source such as airflow louvers or vibrating mounts. In another embodiment, the signal contains the power consumption as an indicator of the operational state of the sound source. The resonator array may be the resonator array 100 of FIG. 1, the resonator array 300 of FIG. 3, or any other resonator described in the embodiments of the present disclosure.

The method of FIG. 4 also includes altering 402, based on the received signal, the frequency of sound attenuated by resonators included in the resonator array. Altering 402 the frequency of sound attenuated by resonators may be carried out by a controller coupled to (or included within) the resonator array in response to, and based on, the received signal 401. Altering 402 the frequency of sound attenuated by resonators includes altering 404 a volume of the cavity included in each resonator within the resonator array. Altering 404 the volume of the cavities in the resonators may be carried out by the controller activating a physical mechanism, such as the motor 102 of FIG. 1, the compressor 302 of FIG. 3, a hydraulic mechanism, a piezoelectric mechanism, or any other physical mechanism configured to change the volume of the cavities. Not included in FIG. 3, the method may further include activating one or more other physical mechanisms included within the resonator array to alter one or more of the length of the neck of the resonators and the diameter of the opening of the neck of the resonators.

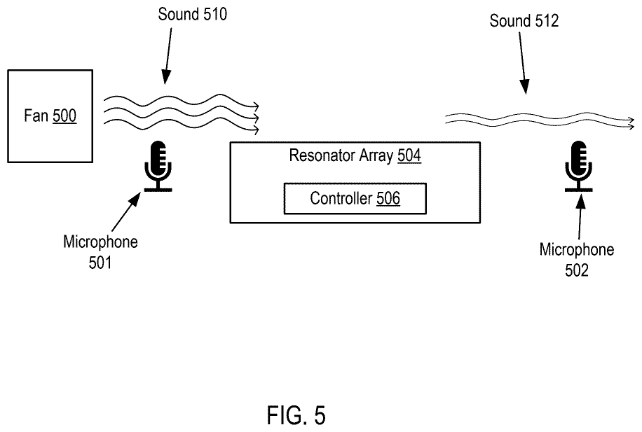

For further explanation, FIG. 5 sets forth a line drawing of a system configured for tuning a resonator array in accordance with embodiments of the present disclosure. FIG. 5 shows a system that includes a fan 500, a microphone 501, a resonator array 504, a controller 506, and a microphone 502. The controller is depicted in FIG. 5 as being included within the resonator array 504. In another embodiment, the controller is external to the resonator array, and coupled to it (either physically or wirelessly). The example fan 500 of FIG. 5 is shown as emitting a sound 510. However, the fan 500 of FIG. 5 is shown merely as one example element that emits sound. In other embodiments, any other device, component, or system which emits sound (independent of whether the sound source emits sound at a constant frequency or in varying frequencies) may replace the fan of FIG. 5 (such as a motor, a pump, a compressor, a server rack, and the like). The example resonator array 504 is positioned proximate to the fan, where the sound coming from the fan passes by the resonator array. As shown in FIG. 5, the sound is reduced by the resonator array so that the sound continuing on past the resonator array (such as sound 512) is weaker or smaller than the sound 510 emitted by the fan 500.

The resonator array of FIG. 5 is configured to attenuate sounds surrounding, or moving past, the resonator array. By positioning the resonator array close to (or in line with) the fan 500, the resonator array may attenuate the sound emitted by the fan. In one embodiment, ducting may be used to route the sound from the sound source (such as the example fan in the embodiment of FIG. 5) to the resonator array for attenuation. For example, ducting could route sound to the resonator array or a resonator array could be included within ducting for sound attenuation. The example of FIG. 5 shows a microphone 501 positioned between the resonator array and the fan. The microphone 501 is communicatively coupled to the resonator array or the controller and is configured to record data describing the sound emitted from the fan and send the data to the resonator array or controller. The controller is configured to analyze the received data from the microphone and determine the frequency of sound to tune the resonator array to best attenuate the sound captured by the microphone. In one embodiment, determining the frequency of sound to tune the resonator array to best attenuate the sound captured by the microphone includes determining which frequency of sound captured by the microphone is loudest or has the highest amplitude. In another embodiment, the frequency of sound selected for attenuation may be selected based on how annoying the frequency is for persons proximate to the sound source. Such frequencies may be determined based on one or more sound quality metrics, weighting the impact of one or more frequencies, or referencing stored data associated with different frequencies (where such data may be based on one or more models or surveys). The frequency attenuated by the resonator array may also be user selected, such as in response to receiving the data from the microphone. In another embodiment, the controller is configured to perform machine learning to determine which frequency sounds captured by the microphone are most likely to be selected by a user for attenuation.

Once the controller determines the frequency of sound to attenuate by the resonator array, the controller is configured to tune the resonator array to match the determined frequency. That is, the resonating frequency of the resonators included in the resonator array are tuned by the controller 506 so that they match the determined frequency. Tuning the resonator array may be carried out according to the method shown in FIG. 4, and the method described in reference to FIGS. 1-3. By tuning the resonator array based on data captured by the microphone, the controller is configured to automatically detect sound proximate to the resonator array and tune to the resonator array to attenuate such sound.

The example system of FIG. 5 also includes microphone 502 positioned beyond the resonator array relative to the fan. The microphone 502 of FIG. 5 is communicatively coupled to the resonator array (or the controller) and is configured to record data describing the sound emitted by the fan that has already been attenuated by the resonator array. The microphone 502 is also configured to send the captured data to the resonator array or controller. The controller 506 is configured to analyze the received data from the microphone 502 and determine the performance of the resonator array. Determining the performance of the resonator array includes determining, by the controller, what percentage of sound was attenuated by the resonator array. Specifically, the controller is configured to analyze the determined frequency of sound captured by the microphone 502 and compare it with the data describing the determined frequency of sound captured by the first microphone 501. By comparing the sound leaving the resonator array with the sound arriving at the resonator array, the controller is configured to calculate the performance of the resonator array.

After determining the performance of the resonator array, the controller is configured to adjust the resonator array, by further tuning the resonators included within it, to increase the performance of the resonator array. Further tuning the resonator array may be carried out responsive to determining, by the controller, that the performance of the resonator array is lower than a threshold amount. For example, after comparing the sound leaving the resonator array with the sound arriving at the resonator array, the controller may determine that the attenuation of sound at the determined frequency is lesser than acceptable when compared to a threshold value (where the threshold may be user selectable or automatically calculated by the controller). Upon determining that the performance of the resonator array does not meet the threshold value, the controller is configured to further adjust the frequency targeted by the resonators included in the resonator array to increase the performance of the resonator array. The controller may go through multiple iterations of further adjusting the array and calculating updated performance levels before arriving at a performance that satisfies the threshold value. The controller is configured to perform machine learning when iteratively improving the performance of the resonator array in order to increase the accuracy of adjustments made to the resonator array when optimizing performance.

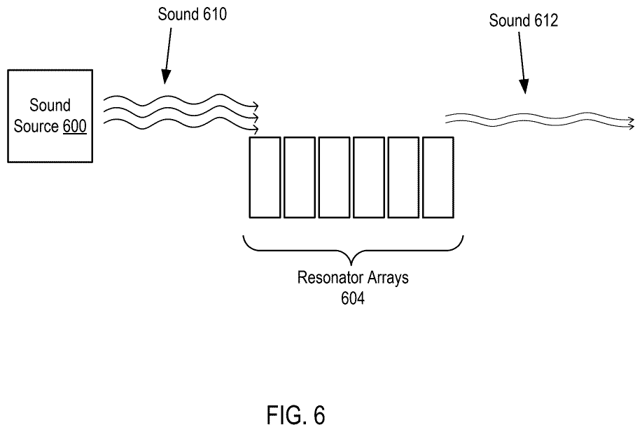

For further explanation, FIG. 6 sets forth a line drawing of another system configured for tuning a resonator array in accordance with embodiments of the present disclosure. FIG. 6 differs from the system of FIG. 5 in that the system of FIG. 6 includes multiple resonator arrays 604 being used simultaneously to attenuate sound 610 coming from a sound source 600. In one embodiment, all of the resonator arrays 604 are tuned to attenuate the same frequency, where the use of multiple resonator arrays allows for an increased level of attenuation of the specific frequency targeted by the resonator arrays. In another embodiment, one or more resonator arrays may be tuned to attenuate different frequencies, so that multiple frequencies may be targeted (for attenuation) from the sound source. In one embodiment, each resonator array of the resonator arrays 604 includes its own actuator or physical mechanism for tuning the frequency of the resonators in that array. The actuators may all be of the same type or one or more of the resonator arrays may include different types of actuators or physical mechanisms (such as pistons, compressors, pneumatic devices, flexible membranes, hydraulic devices, mechanical arms, and the like). In one embodiment, there may be a single controller configured to control all of the resonator arrays, where the controller is configured to control each resonator array independently. In another embodiment, each resonator array may have its own separate controller configured to control the array and tune the included resonators to attenuate a specific frequency.

The sound source 600 of FIG. 6 may be any device, component, or system which emits sound. The sound source may emit sound at a constant frequency or the sound source may emit varying frequencies that change over time. The example resonator array 604 is positioned proximate to the sound source, where the sound coming from the sound source passes by the resonator arrays. As shown in FIG. 6, the sound is reduced by the resonator array so that the sound continuing on past the resonator array (such as sound 612) is weaker or smaller than the sound 610 emitted by the sound source 600. The resonator arrays of FIG. 6 are configured to attenuate sounds surrounding, or moving past, the resonator array. By positioning the resonator arrays close to (or in line with) the sound source 600, the resonator array may attenuate the sound emitted by the sound source. In one embodiment, ducting may be used to route the sound from the sound source to the resonator array for attenuation. For example, ducting could route sound to the resonator arrays or the resonator arrays could be included within ducting for sound attenuation.

In view of the explanations set forth above, readers will recognize that the benefits of tuning a resonator array according to embodiments of the present disclosure include:
Increasing resonator array performance by calculating the performance and further tuning the resonator array.
Increasing resonator array efficiency by allowing for a single physical mechanism to adjust all of the resonators in the array simultaneously.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

It will be understood from the foregoing description that modifications and changes may be made in various embodiments of the present disclosure without departing from its true spirit. The descriptions in this specification are for purposes of illustration only and are not to be construed in a limiting sense. The scope of the present disclosure is limited only by the language of the following claims.

What is claimed is:

1. An apparatus comprising:
a plurality of resonators each configured to attenuate sound at a specific frequency, wherein each of the plurality of resonators includes a cavity and a neck coupled to the cavity; and
a physical mechanism configured to change the specific frequency of sound attenuated by each of the plurality of resonators, including altering, by the physical mechanism, a volume included in each of the plurality of resonators.

2. The apparatus of claim 1, wherein the physical mechanism includes a pneumatic mechanism configured to alter the volume of the cavity included in each of the plurality of resonators by pressurizing a space surrounding all of the cavities of the resonators.

3. The apparatus of claim 1, wherein each of the cavities is surrounded by a flexible membrane, and wherein the physical mechanism includes a mechanical connection coupled to each of the flexible membranes.

4. The apparatus of claim 3, wherein altering the volume of the cavities includes moving the mechanical connection to shift a portion of the membrane of each of the resonators.

5. The apparatus of claim 1, wherein the physical mechanism includes a piezoelectric mechanism configured to compress or expand one or more walls of each of the cavities.

6. The apparatus of claim 1, wherein each of the resonators includes one or more of a diaphragm comprising a flexible membrane and a piston comprising a sliding barrier configured to alter the volume of the cavity.

7. The apparatus of claim 1, wherein the volume altered by the physical mechanism comprises one or more of: a volume of the cavity and a volume of the neck.

8. The apparatus of claim 7, wherein altering the volume of the neck includes altering one or more of: a length of the neck and a diameter of the neck.

9. The apparatus of claim 1, further comprising one or more additional physical mechanisms configured to alter one or more additional volumes included in each of the plurality of resonators.

10. The apparatus of claim 1, further comprising a controller configured to receive signals and cause the physical mechanism to adjust the specific frequency of sound attenuated by each of the plurality of resonators in response to the received signals.

11. A method of altering an absorption frequency targeted by a resonator array, the method comprising:
receiving, by a resonator array including a plurality of resonators, a signal, wherein each of the plurality of resonators is configured to attenuate sound at a specific frequency and includes a cavity and a neck coupled to the cavity; and
altering, by a physical mechanism coupled to the cavities of the resonators and based on the received signal, the specific frequency of sound attenuated by each of the plurality of resonators, including altering a volume included in each of the plurality of resonators.

12. The method of claim 11, wherein the signal specifies one or more frequencies of sound proximate to the resonator array.

13. The method of claim 11, wherein the physical mechanism includes a pneumatic mechanism, and wherein altering the specific frequency includes pressurizing, by the pneumatic mechanism, a space surrounding all of the cavities of the resonators.

14. The method of claim 11, wherein each of the cavities is surrounded by a flexible membrane, and wherein the physical mechanism includes a mechanical connection coupled to each of the flexible membranes.

15. The method of claim 14, wherein altering the volume of the cavities includes moving the mechanical connection to shift a portion of the membrane of each of the resonators.

16. The method of claim 11, wherein the physical mechanism includes a piezoelectric mechanism configured to compress or expand one or more walls of each of the cavities.

17. The method of claim 11, wherein each of the resonators includes one or more of a diaphragm comprising a flexible membrane and a piston comprising a sliding barrier and configured to alter the volume of the cavity.

18. A system comprising:
a sound source;
a resonator array positioned in front of the sound source, the resonator array comprising:
a plurality of resonators each configured to attenuate sound at a specific frequency, wherein each of the plurality of resonators includes a cavity and a neck coupled to the cavity; and
a physical mechanism configured to alter the specific frequency of sound attenuated by each of the plurality of resonators, including modifying, by the physical mechanism, a volume of the cavity included in each of the plurality of resonators; and
a controller coupled to the resonator array and configured to move the physical mechanism to alter one or more specific frequencies of sound attenuated by the resonator array.

19. The system of claim 18, further comprising one or more measuring devices coupled to the resonator array, wherein the one or more measuring devices are configured to obtain system operational characteristics related to sound emitted by the sound source, wherein the controller is coupled to the one or more measuring devices and is configured to determine one or more frequencies based on data obtained by the one or more measuring devices.

20. The system of claim 19, wherein the controller is configured to perform machine learning on the data obtained by the one or more measuring devices to adjust the physical mechanism based on a performance of the resonator array.
